(19) United States
(12) Patent Application Publication
(10) Pub. No.: US 2024/0371744 A1
(43) Pub. Date: Nov. 7, 2024

(54) ARRAY SUBSTRATE, DISPLAY PANEL AND DISPLAY DEVICE

(71) Applicant: KunShan Go-Visionox Opto-Electronics Co., Ltd, Kunshan (CN)

(72) Inventors: Wenxing LI, Kunshan (CN); Gongzheng ZANG, Kunshan (CN)

(73) Assignee: KunShan Go-Visionox Opto-Electronics Co., Ltd, Kunshan (CN)

(21) Appl. No.: 18/775,148

(22) Filed: Jul. 17, 2024

Related U.S. Application Data
(63) Continuation of application No. PCT/CN2022/127586, filed on Oct. 26, 2022.

(30) Foreign Application Priority Data
Aug. 24, 2022 (CN) 202211016526.X

(51) Int. Cl. H01L 23/498

(52) U.S. Cl. CPC H01L 23/4985; H01L 23/49838

(57) ABSTRACT

An array substrate, a display panel and a display device are provided by the present application. The array substrate includes a first body, a bending part and a second body arranged in a first direction. The first body is connected to the second body through the bending part. The bending part includes a bending body and a first connecting part arranged on a side of the bending body near the first body, the first connecting part includes a first connecting segment and at least one first external expansion segment located on at least one side of the first connecting segment in the second direction, the bending body is connected to the first body through the first connecting segment, and in the first direction, two ends of the bending body in the second direction are flush with two ends of the first connecting segment in the second direction, respectively.

### CROSS REFERENCE TO RELATED APPLICATION

The present application is a continuation of International Application No. PCT/CN2022/127586, filed on Oct. 26, 2022, which claims priority to Chinese Patent Application No. 202211016526.X, filed on Aug. 24, 2022, titled with “ARRAY SUBSTRATE, DISPLAY PANEL AND DISPLAY DEVICE”, all of which are hereby incorporated by reference in their entireties.

### TECHNICAL FIELD

The present application relates to the technical field of display, and in particular to an array substrate, a display panel and a display device.

### BACKGROUND

With the development of science and technology, display devices have been rapidly developed. Currently, small-sized display devices such as an electronic watch have been increasingly widely used. However, the small-sized display devices significantly increase the difficulty of manufacture. Therefore, how to improve the yield of the small-sized display devices has become an urgent problem to be solved.

### SUMMARY

The present application provides an array substrate, a display panel and a display device, which can improve the product yield.

Embodiments in the present application provide an array substrate, including a first body, a bending part and a second body arranged in a first direction. The first body is connected to the second body through the bending part, a maximum width of the bending part in a second direction is smaller than a maximum width of the first body in the second direction, and the first direction intersects with the second direction. The bending part includes a bending body and a first connecting part arranged on a side of the bending body near the first body, the first connecting part includes a first connecting segment and at least one first external expansion segment located on at least one side of the first connecting segment in the second direction, the bending body is connected to the first body through the first connecting segment, and in the first direction, two ends of the bending body in the second direction are flush with two ends of the first connecting segment in the second direction, respectively.

In a second aspect, embodiments in the present application provide a display panel, including the array substrate according to any one of the embodiments as described above and a light-emitting member layer. An orthographic projection of the light-emitting member layer on the array substrate is located within the first body.

In a third aspect, embodiments in the present application provide a display device, including the display panel according to any one of the embodiments as described above.

In the embodiments of the present application, by arranging the first external expansion segment and positioning the first external expansion segment on at least one side of the first connecting segment in the second direction, the strength of an end of the first connecting segment in the second direction can increase. Moreover, due to the size of the first external expansion segment, the stress intensity at a position of the end can be dispersed, so that the risk of the stress concentration at a position of the end can be reduced. In addition, the first external expansion segment can also increase a width size of the first connecting part in the second direction. By increasing the width size, the structural strength of the first connecting part can be enhanced, and the reliability of the first connecting part can be improved.

### BRIEF DESCRIPTION OF THE DRAWINGS

In order to more clearly illustrate the technical solution of the embodiments of the present application, the drawings required to be used in the embodiments of the present application will be briefly introduced below. Obviously, the drawings described below only show some embodiments of the present application. For those skilled in the art, other drawings can also be obtained according to these drawings without the inventive labor.

FIG. 1 shows a structural schematic view of an array substrate according to an embodiment of the present application;

FIG. 2 shows a structural schematic view of an array substrate according to another embodiment of the present application;

FIG. 3 shows an enlarged schematic view of region Q in FIG. 1;

FIG. 4 shows a torque test diagram of different array substrates in different comparative examples;

FIG. 5 shows an enlarged local schematic view of an array substrate according to another embodiment of the present application;

FIG. 6 shows a layout schematic view of a wiring of an array substrate according to another embodiment of the present application;

FIG. 7 shows an enlarged schematic view of region P in FIG. 6;

FIG. 8 shows a layout schematic view of a wiring of an array substrate according to another embodiment of the present application;

FIG. 9 shows a structural schematic view of an array substrate according to another embodiment of the present application;

FIG. 10 shows a structural schematic view of an array substrate according to another embodiment of the present application;

FIG. 11 shows an enlarged schematic view of region O in FIG. 10;

FIG. 12 shows a structural schematic view of a display panel according to an embodiment of the present application; and

FIG. 13 shows a structural schematic view of a display device according to an embodiment of the present application.

### DETAILED DESCRIPTION

Embodiments of the present application will be further described in detail according to the drawings and examples below. The detailed description and drawings of the following embodiments are used to exemplarily illustrate the principles of the present application, but cannot be used to limit the scope of the present application, that is, the present application is not limited to the described embodiments.

Currently, various small-sized flexible display panels are presented in the market, and include various wearable products such as an electronic watch. Since such display panel has a small volume, generally, the requirement of system integration is high, and a structural size of a non-display region is greatly compressed. In order to meet the wiring need of the display panel, in many solutions, the non-display region of the display panel is bent to a side of a backlight face of the display panel to improve the display effect of the display panel.

During the manufacturing process of the display panel, there is a bending region between the display region and the non-display region of the display panel, and the non-display region can be bent to the side of the backlight face of the display panel through the bending region. Generally, a width of the bending region is small, and a width of the display panel near the bending region will rapidly decrease. During a module operation, such as a manual operation, due to uneven stress distribution, it is prone to a significant stress at a connection between the bending region and the display region, resulting in the stress concentration at the connection. Further, it is prone to cause the crack phenomenon between the bending region and the display region, which can affect the yield of the display panel.

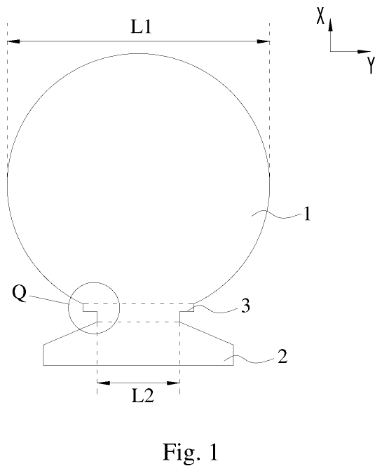

In order to solve the above problems, referring to FIG. 1 and FIG. 3, embodiments of the present application provide an array substrate including a first body 1, a bending part 3 and a second body 2 arranged in a first direction X. The first body 1 is connected to the second body 2 through the bending part 3, a maximum width of the bending part 3 in a second direction Y is smaller than a maximum width of the first body 1 in the second direction Y, and the first direction X intersects with the second direction Y.

The bending part 3 includes a bending body 31 and a first connecting part 32 arranged on a side of the bending body 3 near the first body 1, the first connecting part 32 includes a first connecting segment 321 and at least one first external expansion segment 322 located on at least one side of the first connecting segment 321 in the second direction Y, the bending body 31 is connected to the first body 1 through the first connecting segment 321, and in the first direction X, two ends of the bending body 31 in the second direction Y are flush with two ends of the first connecting segment 321 in the second direction Y, respectively.

The first body 1, the bending part 3 and the second body 2 are arranged side by side in sequence in the first direction X. The first body 1 of the array substrate corresponds to a display region of the display panel, and the second body 2 of the array substrate corresponds to a non-display region of the display panel. The second body 2 can be bent to a side of a back face of the first body 1 through the bending part 3, so that the first body 1 overlaps with the second body 2 in the thickness direction of the array substrate.

It should be noted that the “display region of the display panel” mentioned in the embodiments of the present application refers to: most of a region of the display panel at a corresponding position of the first body 1 is the display region. Of course, at the corresponding position of the first body 1 in the display panel and located on a peripheral side of the display region, there may be a small portion of the region for arranging wiring, which cannot achieve the display effect. Alternatively, the display panel may be a full screen display panel, which means that all of the region of the display panel at the corresponding position of the first body 1 is the display region, and the embodiments of the present application do not limit this.

The maximum width of the bending part 3 in the second direction Y is smaller than the maximum width of the first body 1 in the second direction Y, and the second direction Y may be the width direction of the first body 1. The first direction X intersects with the second direction Y, and the embodiments of the present application do not limit a magnitude of an angle between the first direction X and the second direction Y. Exemplarily, the first direction X is perpendicular to the second direction Y.

The embodiments of the present application do not limit the contour and shape of the first body 1. Exemplarily, the first body 1 is a circular structure, and in a direction of the first body 1 towards the bending region, the width of the first body 1 in the second direction Y gradually increases firstly, and then decreases gradually. Alternatively, the first body 1 is a triangular structure, and in the direction of the first body 1 towards the bending region, the width of the first body 1 in the second direction Y gradually decreases. The width of the array substrate at the connection between the bending part 3 and the first body 1 rapidly changes. Therefore, during the module operation, due to the uneven force on the array substrate, it is prone to the phenomenon of the stress concentration at the connection between the bending part 3 and the first body 1. Therefore, the embodiments of the present application has improved the structure of the bending part 3.

Specifically, the bending part 3 includes the bending body 31 and the first connecting part 32 arranged side by side in the first direction X, and the first connecting part 32 is located between the bending body 31 and the first body 1. The bending body 31 is a region in the bending part 3 that realizes the bending effect, and the first connecting part 32 is a region in the bending part 3 used to connect with the first body 1. Although the first connecting part 32 is not bent during the bending process, the first connecting part 32 is a region which is most susceptible to be impacted and cause the problem in the bending part 3 during the bending process or other module operations.

The first connecting part 32 includes the first connecting segment 321, which can realize the connection between the first body 1 and the bending body 31. In other words, a size of the first connecting segment 321 in the second direction Y is the same as a size of the bending body 31 in the second direction Y, and in the first direction X, two ends of the bending body 31 in the second direction Y are flush with two ends of the first connecting segment 321 in the second direction Y, respectively. Therefore, the first connecting segment 321 can achieve the connection between the first body 1 and the bending body 31.

In addition to the first connecting segment 321, the first connecting segment 32 further includes the first external expansion segment 322. The first external expansion segment 322 is located on at least one side of the first connecting segment 321 in the second direction Y. The first connecting segment 321 and the first external expansion segment 322 may be an integrated structure. Similar to the first connecting segment 321, the first external expansion segment 322 is also connected to the first main body 1; the difference is that the first external expansion segment 322 is not connected to the bending body 31.

It can be seen from the above content, it is prone to the phenomenon of the stress concentration at the connection between the bending part 3 and the first body 1. In a display panel in the related art, the connection between the bending part 3 and the first body 1 is an end of the first connecting segment 321 in the second direction Y, where is prone to crack or other problems.

In the embodiments of the present application, by arranging the first external expansion segment 322 and positioning the first external expansion segment 322 on at least one side of the first connecting segment 321 in the second direction Y, the strength of the end of the first connecting segment 321 in the second direction Y can be improved. Moreover, due to the size of the first external expansion segment 322, the stress intensity at a position of the end can be dispersed, so that the risk of the stress concentration at a position of the end can be reduced.

In addition, the first external expansion segment 322 can also increase the width size of the first connecting part 32 in the second direction Y, and the increase in the width size means that the structural strength of the first connecting part 32 can be enhanced, thereby improving the reliability of the first connecting part 32. Optionally, at least two first external expansion segments 322 are provided. In some embodiments, two first external expansion segments 322 are provided. The two first external expansion segments 322 are arranged at two ends of the first connecting segment 321 in the second direction Y, respectively.

It should be noted that the array substrate provided by the embodiments of the present application is suitable for the display panel that requires bending the non-display region to a side of the backlight face. For other film layers in the display panel in addition to the array substrate, other portions of the film layers will also be bent with the array substrate. Therefore, the portion of the film layers can also be the same shape and contour as the array substrate provided by the embodiments of the present application, which is not limited by the embodiments of the present application.

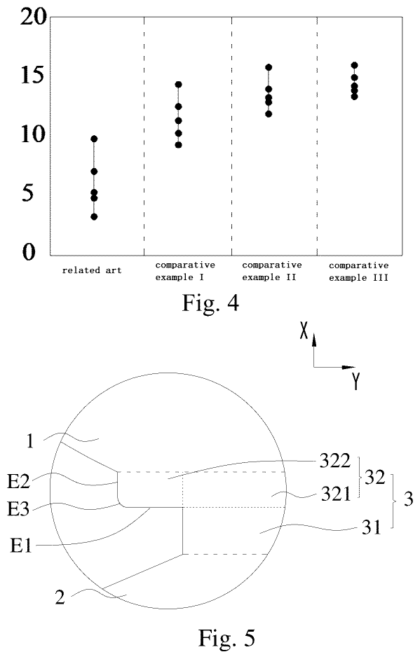

After a plurality of experimental tests, the applicant obtains the data shown in FIG. 4. Herein, the data in a vertical direction represents the torque value, and the diagram represents the maximum torques that the array substrate can withstand under four different conditions and the plurality of experimental tests. The related art refers to an array substrate without the first external expansion segment 322, and all of comparative example I, comparative example II and comparative example III refer to the array substrate with the first external expansion segment 322. The difference among comparative example I, comparative example II and comparative example III is that the width of the first external expansion segment 322 in the second direction is different. The width of the first external expansion segment 322 in the second direction in comparative example III is larger than that of comparative example II, and the width of the first external expansion segment 322 in the second direction in comparative example II is larger than that of comparative example I.

By comparing the related art with comparative example I, it can be seen that the first external expansion segment 322 can significantly increase the maximum allowable torque of the array substrate. Specifically, in a case without arranging the first external expansion segment 322, the average allowable torque of the array substrate under a certain condition is 6.19 N·mm; in a case of arranging the first external expansion segment 322 and setting the size of the first external expansion segment 322 in the second direction Y to 0.8 mm, the average allowable torque of the array substrate under the same condition is 12.81 N·mm.

Furthermore, comparing with comparative example I, comparative example II and comparative example III, it can be seen that the larger the width of the first external expansion segment 322 in the second direction Y is, the larger the average torque of the corresponding array substrate under the same condition is, and more reliable the structure of the array substrate is.

In some embodiments, a first edge E1 is arranged on a side of the first external expansion segment 322 away from the first body 1 in the first direction X, and a second edge E2 is arranged on a side of the first external expansion segment 322 away from the first connecting segment 321 in the second direction Y; and at least one of the first edge E1 or the second edge E2 is a curved structure.

In the embodiments of the present application, the first external expansion segment 311 is located on at least one side of the first connecting part 32 in the second direction Y. On this basis, in order to reduce the impact of an outer contour of the first external expansion segment 311 on the tactile feel of the display panel, in the embodiments of the present application, at least one of the first edge E1 or the second edge E2 in the first external expansion segment 311 is the curved structure. Exemplarily, each of the first edge E1 and the second edge E2 is an arc-shaped structure. According to this design, the tactile feel at the position of the first external expansion segment 311 can be improved. In addition, according to this design, when the first external expansion segment 311 is impacted by the external force, the buffering effect to a certain extent can be achieved, and the reliability can be improved.

In some embodiments, as shown in FIG. 3, the first edge E1 extending in the second direction Y is arranged on a side of the first external expansion segment 322 away from the first body 1 in the first direction X, and the second edge E2 extending in the first direction X is arranged on a side of the first external expansion segment 322 away from the first connecting segment 321 in the second direction Y.

In a display panel in the related art, an arc angle structure is often used for transitional connection between the bending part 3 and the first body 1, and generally, the arc angle structure protrudes towards the direction towards the first body 1, that is, the arc angle structure protrudes inward. This design leads to the stress concentration problem at the position of the arc angle structure, which is not conducive to the manufacture of the display panel.

In the embodiments of the present application, the first external expansion segment 322 includes the first edge E1 and the second edge E2, the first edge E1 extends in the second direction Y, and the second edge E2 extends in the first direction X. In this design, the first external expansion segment 322 protrudes in a direction away from the first body 1, that is, the first external expansion segment 322 is formed by protruding outward. Compared with the arc-shaped structure in related art, the first external expansion segment 322 provided by the embodiments of the present application can further increase the size of the first connecting part 32, and can disperse the stress intensity at the connection between the bending part 3 and the first body 1, thereby reducing the risk of stress concentration at this position.

It should be noted that the first edge E1 can be directly connected to the second edge E2 in contact, or the first edge E1 and the second edge E2 can be indirectly connected through another structure. The embodiments of the present application do not limit the connection method and do not limit an angle between the first edge E1 and the second edge E2. The angle between the first edge E1 and the second edge E2 can be an acute angle, a right angle or an obtuse angle.

In some embodiments, the first edge E1 is perpendicular to or at an obtuse angle with the second edge E2.

The first edge E1 and the second edge E2 respectively extend in different directions, and the angle between the first edge E1 and the second edge E2 determines the shape and contour of the first external expansion segment 322. On this basis, in the embodiments of the present application, the first edge E1 is perpendicular to or at the obtuse angle with the second edge E2, thereby avoiding an acute angle between the first edge E1 and the second edge E2.

Specifically, in the case that the angle between the first edge E1 and the second edge E2 is set at the acute angle, if the first edge E1 and the second edge E2 are directly connected, the first external expansion segment 322 will form a sharp end. During using the display panel, it is prone to collision and damage at the connection between the first edge E1 and the second edge E2 under the external force, and the sharp end is easy to harm the user.

Therefore, in order to avoid the above problem, in the embodiments of the present application, the first edge E1 is perpendicular to or at the obtuse angle with the second edge E2. The specific angle size between the first edge E1 and the second edge E2 needs to be determined based on the actual using needs of the display panel, and embodiments of the present application do not limit it.

In some embodiments, referring to FIG. 5, the first external expansion segment 322 further includes an arc-shaped connecting segment E3 connecting the first edge E1 with the second edge E2.

The arc-shaped connecting segment E3 is used to connect the first edge E1 and the second edge E2. The design of the arc-shaped connecting segment E3 allows for a smooth transition at the connection between the first edge E1 and the second edge E2, thereby reducing the risk of collision and damage at the connection between the first edge E1 and the second edge E2, and providing a better using experience to the user.

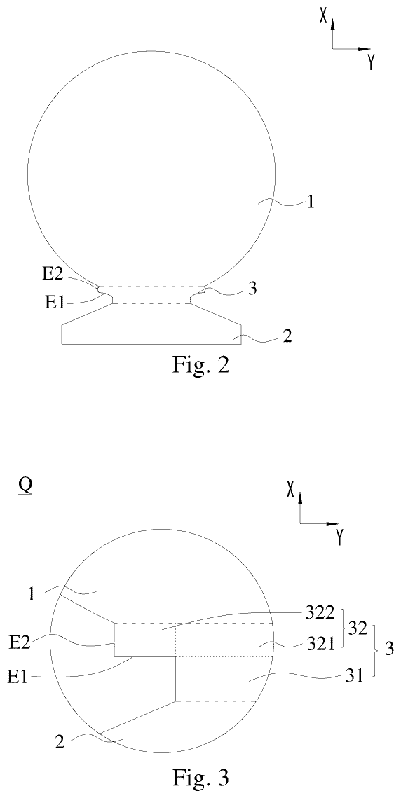

In some embodiments, referring to FIG. 2 and FIG. 5, the array substrate includes at least one first electric-conducting part 11 located inside the first body 1, at least one second electric-conducting part 21 located inside the second body 2 and at least one conductive part 4 located within the bending part 3 connecting the first electric-conducting part 11 with the second electric-conducting part 21. At least a portion of the conductive part 4 is located inside the first external expansion segment 322.

The first electric-conducting part 11 is located in the first body 1. Exemplarily, the array substrate further includes a pixel electrode located in the first body 1, and the first electric-conducting part 11 is electrically connected to the pixel electrode, so as to achieve the luminous effect of the display panel. The second electric-conducting part 21 is located in the second body 2. Exemplarily, the second body 2 further includes a driving chip. The second electric-conducting part 21 is electrically connected to the driving chip, so as to transmit the driving signal in the driving chip to different positions.

The conductive part 4 is located in the bending part 3 and is used to achieve electrical connection between the first electric-conducting part 11 and the second electric-conducting part 21. The conductive part 4 can transmit the signal from the second electric-conducting part 21 to the first electric-conducting part 11, or can transmit the signal from the first electric-conducting part 11 to the second electric-conducting part 21. Optionally, a portion of the first electric-conducting part 11 used to connect with the conductive part 4 is a fan-out structure, and at least a portion of the first electric-conducting part 11 extends along an outer contour of the first body 1; a portion of the second electric-conducting part 21 used to connect with the conductive part 4 is a fan-out structure, and at least a portion of the second electric-conducting part 21 extends along an outer contour of the second body 2.

Since the maximum width of the bending part 3 in the second direction Y is smaller than the maximum width of the first body 1 in the second direction Y, generally, a distance between two conductive parts 4 located in the bending part 3 is smaller than a distance between two first electric-conducting parts 11 located in the first body 1. In other words, the wiring density in the bending part 3 is larger than that the wiring density in the first body 1.

In the display panel in the related art, a dense and complex wiring is arranged near the connection between the bending part 3 and the first body 1. During the wiring manufacturing process, it is often necessary to use the process such as the chemical vapor deposition for film formation. After manufacturing, groove structures are often formed on a surface, resulting in the stress concentration at the microscopic level.

On this basis, in the embodiments of the present application, the problem of stress concentration can be solved by arranging the first external expansion segment 322. In addition, at least a portion of the conductive part 4 is arranged in the first external expansion segment 322, thereby increasing the distance between two adjacent conductive parts 4 located in the first connecting segment 32 and reducing the risk of signal interference. Alternatively, more conductive parts 4 can be arranged win the first connecting part 32, so as to meet the wiring needs of the display panel with high pixel density and improve the display effect of the display panel.

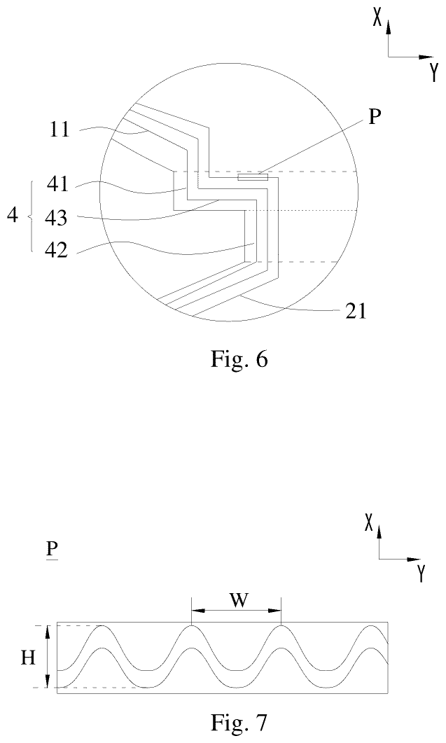

In some embodiments, as shown in FIG. 3 and FIG. 6, the conductive part 4 includes a first sub-segment 41 connected to the first electric-conducting part 11, a second sub-segment 42 connected to the second electric-conducting part 21 and a third sub-segment 43 connected to the first sub-segment 41 and the second sub-segment 42.

The first sub-segment 41 is electrically connected to the first electric-conducting part 11 to achieve the signal transmission with the first electric-conducting part 11. The second sub-segment 42 is electrically connected to the second electric-conducting part 21 to achieve the signal transmission with the second electric-conducting part 21. The two ends of the third sub-segment 43 are electrically connected to the first sub-segment 41 and the second sub-segment 42, respectively, so as to achieve the signal transmission between the first sub-segment 41 and the second sub-segment 42.

In the display panel in the related art, the wiring located between the bending part 3 and the first body 1 and near the arc angle structure is usually an arc-shaped wiring. During module operation, there is the stress concentration effect near the arc angle structure, and the extending direction of the wiring at this position is easily perpendicular to the direction of the force, which means that the wiring at this position is easily subjected to a vertical tangential force, so that it prone to wiring breakage.

In the embodiments of the present application, the conductive part 4 includes the first sub-segment 41, the second sub-segment 42 and a third sub-segment 43. The first sub-segment 41, the second sub-segment 42 and the third sub-segment 43 are three independent parts. By adjusting the extending directions of these three parts, the problem of the extending direction of the wiring being perpendicular to the direction of the force can be avoided, the risk of the conductive part 4 breaking can be reduced and the product yield can be improved.

In some embodiments, the first sub-segment 41 extends in the first direction X and at least a portion of the first sub-segment 41 is located within the first external expansion segment 322.

Since the first sub-segment 41 extends in the first direction X, and the second edge E2 also extends in the first direction X, the first sub-segment 41 is parallel to the second edge E2. During the manufacturing process of the first sub-segment 41, the first sub-segment 41 is arranged to fit the second edge E2 and formed by extending in the direction of the second edge E2.

In the embodiments of the present application, since the first sub-segment 41 extends in the first direction X, during the module operation, the force direction between the bending part 3 and the first body 1 is usually between the first direction X and the second direction Y, which can avoid the extending direction of the first sub-segment 41 being perpendicular to the force direction, reduce the tangential force of the external force exerting on the first sub-segment 41, reduce the risk of fracture of the first sub-segment 41, and improve the yield and reliability.

In some embodiments, the third sub-segment 43 extends in the second direction Y and at least a portion of the third sub-segment 43 is located within the first external expansion segment 322.

Since the third sub-segment 43 extends in the second direction Y, and the first edge E1 also extends in the second direction Y, the third sub-segment 43 is parallel to the first edge E1. In the manufacturing process of the third sub-segment 43, the third sub-segment 43 is arranged to fit the first edge E1 and formed by extending in the direction of the first edge E1.

In the embodiments of the present application, as the third sub-segment 43 extends in the second direction Y, during the module operation, the force direction between the bending part 3 and the first body 1 is usually between the first direction X and the second direction Y, which can avoid the extending direction of the third sub-segment 43 being perpendicular to the force direction, reduce the tangential force of the third sub-segment 43, reduce the risk of fracture of the third sub-segment 43, and improve the yield and reliability.

In addition, the embodiments of the present application do not limit the extending direction of the second sub-segment 42. Exemplarily, the second sub-segment 42 extends in the first direction X, that is, the second sub-segment 42 is parallel to the first sub-segment 41.

In some embodiments, referring to FIG. 6 and FIG. 7, at least one of the first sub-segment 41, the second sub-segment 42 or the third sub-segment 43 is in a wave shape. Optionally, all the first sub-segment 41, the second sub-segment 42 and the third sub-segment 43 are in wave shape.

The design of wave shape can reduce the risk of fracture of the conductive part 4. Specifically, due to the influence of the external stress, the conductive part 4 is prone to fracture under the pulling action of the external force, which may lead to the connection failure or poor performance. In view of this, at least one of the first sub-segments 41, the second sub-segment 42 or the third sub-segment 43 is in the wave shape; since the wave-shaped structure itself has a certain elastic and compressive capacity, the overall strength of the conductive part 4 can be improved and the conductive part 4 can still ensure its complete and reliable structure under the external force.

The embodiments of the present application do not limit the specific structure of the wave-shaped wiring. Exemplarily, in the wave-shaped wiring, each two adjacent peaks are aligned with each other and each two adjacent valleys are aligned with each other. A wave depth H, which is a height difference between the peak and valley, is larger than a wave width W, which is a distance between each two adjacent peaks.

It should be noted that when the first sub-segment 41, the second sub-segment 42 and the third sub-segment 43 are wave-shaped, the extending direction of the first sub-segment 41 and the third sub-segment 43 is the overall extending trend of the wave-shaped structure. Exemplarily, the extending direction of the first sub-segment 41, the second sub-segment 42 and the third sub-segment 43 can be a direction of a connecting line between adjacent wave peaks in the corresponding wave-shaped structure.

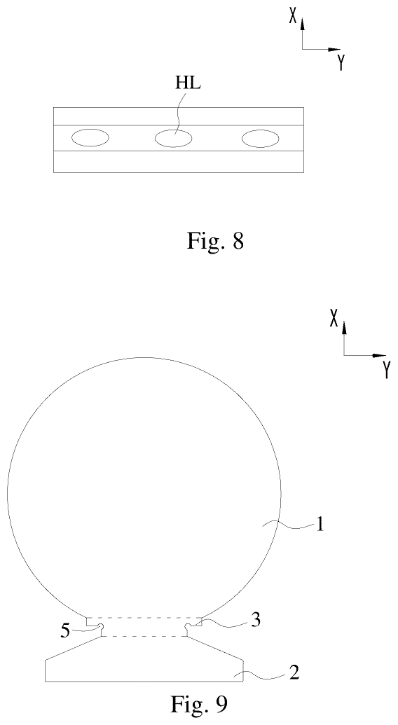

In some embodiments, referring to FIG. 3 and FIG. 8, at least one of the first sub-segment 41, the second sub-segment 42 or the third sub-segment 43 is provided with a through hole HL that penetrates in the thickness direction of the array substrate. Optionally, each of the first sub-segment 41, the second sub-segment 42 and the third sub-segment 43 is provided with the through hole HL.

The embodiments of the present application do not limit the number of through holes HL and the specific positions of through holes HL relative to the first sub-segment 41, the second sub-segment 42 or the third sub-segment 43. Exemplarily, the first sub-segment 41 is provided with a plurality of through holes HL, which are arranged side by side in the second direction Y, that is, the plurality of through holes HL are arranged side by side in the extending direction of the first sub-segment 41.

The through-hole HL can reduce the risk of fracture in the first sub-segment 41, second sub-segment 42 and third sub-segment 43. Specifically, at a position of the through-hole HL, at least one of the first sub-segment 41, second sub-segment 42 or third sub-segment 43 can form two sub-segments which are connected with each other on two sides of the through-hole HL. The two sub-segments enables at least one of the first sub-segment 41, the second sub-segment 42 or the third sub-segment 43 to have a certain elastic recovery force, thereby improving the strength of the conductive part 4.

In some embodiments, a thickness of the conductive part 4 is larger than a thickness of at least one of the first electric-conducting part 11 or the second electric-conducting part 21.

The “thickness of the conductive part 4” mentioned in the embodiments of the present application refers to a size of the conductive part 4 in the thickness direction of the array substrate. Similarly, the thicknesses of the first electric-conducting part 11 and the second electric-conducting part 21 refer to sizes of the first electric-conducting part 11 and the second electric-conducting part 21 in the thickness direction of the array substrate, respectively.

Generally, the thickness of the wiring is positively correlated with the strength of the wiring itself. Therefore, the larger the thickness of the conductive part 4 is, the stronger the strength of the conductive part 4 is, and the lower the risk of fracture is. On this basis, in the embodiments of the present application, the thickness of the conductive part 4 is larger than at least one of the first electric-conducting part 11 or the second electric-conducting part 21, thereby reducing the risk of fracture of the conductive part 4 during the module operation and improving the product yield. Optionally, the thickness of the conductive part 4 is larger than the thickness of the first electric-conducting part 11 and the thickness of the second electric-conducting part 21.

In addition, generally, the thickness of the wiring is negatively correlated with the electric resistance of the wiring itself. Therefore, the electric resistance of the conductive part 4 can be reduced by increasing the thickness of the wiring, thereby reducing the loss of the current and voltage at the conductive part 4, and improving the signal transmission effect of the first electric-conducting part 11 and the second electric-conducting part 21.

In some embodiments, the thickness of the conductive part 4 is H1, the thickness of the first electric-conducting part 11 is H2, and H1 and H2 satisfy: 1000 Å≤H1−H2≤3000 Å.

It can be seen from the above content, by increasing the thickness of the conductive part 4, the strength of the conductive part 4 can be improved and the electric resistance of the conductive part 4 can be reduced. However, if the thickness of the conductive part 4 is almost the same as that of the first electric-conducting part 11, it indicates that the enhancement effect on the strength of the conductive part 4 is insufficient; if the thickness deviation between the conductive part 4 and the first electric-conducting part 11 is too large, it is easy to cause an excessive thickness of the film layer at the position of the conductive part 4, which is not conducive to the manufacture of the display panel.

Therefore, in the embodiments of the present application, the thickness difference H1-H2 between the conductive part 4 and the first electric-conducting part 11 is set between 1000 Å and 3000 Å, thereby improving the strength of the conductive part 4 and avoiding the excessive thickness of the film layer at the position of the conductive part 4. Exemplarily, the thickness difference H1−H2 between the conductive part 4 and the first electric-conducting part 11 may be 1000 Å, 1500 Å, 2000 Å, 2500 Å or 3000 Å.

In some optional embodiments, the thickness of the second electric-conducting part 21 is H3, and H1 and H3 satisfy: 1000 Å≤H1−H3≤3000 Å. Exemplarily, the thickness difference H1−H3 between the conductive part 4 and the second electric-conducting part 21 may be 1000 Å, 1500 Å, 2000 Å, 2500 Å or 3000 Å. Furthermore, the thickness H2 of the first electric-conducting part 11 may be the same as the thickness H3 of the second electric-conducting part 21.

In some embodiments, referring to FIG. 3 and FIG. 9, a connecting end between the bending body 31 and the first external expansion segment 322 is recessed in a direction towards the first body 1 to form at least one groove structure 5.

The connecting end between the bending body 31 and the first external expansion segment 322 is located on at least one side of the bending part 3 in the second direction Y. During the module operation, the connecting end between the bending body 31 and the first external expansion segment 322 is a position that is most prone to the stress concentration in the array substrate.

In the embodiments of the present application, the groove structure 5 is arranged at the position and formed by recessing in the direction towards the first body 1. The embodiments of the present application do not limit the specific shape of the groove structure 5. Exemplarily, the groove structure 5 is an arc-shaped groove structure. The embodiments of the present application do not limit the specific concave direction of the groove structure 5. Exemplarily, the concave direction of groove structure 5 is set at a 45° angle with the first direction X.

To some extent, the groove structure 5 can disperse the stress at the connecting end between the bending body 31 and the first external expansion segment 322, thereby reducing the risk of crack. If the crack occurs, the groove structure 5 can also reduce the risk of the crack spreading towards the first body 1, thereby effectively preventing the wiring breakage and ensuring that the display region of the display panel can normally display.

In some embodiments, there are two groove structures 5 symmetrically distributed on two sides of the bending part 3 in the second direction Y.

Generally, there are two connecting ends between the bending body 31 and the first external expansion segment 322, which are located on two sides of the bending part 3 in the second direction Y. In this case, in the embodiments of the present application, there are two groove structures 5 correspondingly, and the two groove structures 5 are symmetrically distributed on two sides of the bending part 3 in the second direction Y, that is, the two groove structures 5 are arranged on the two connecting ends between the bending body 31 and the first external expansion segment 322, respectively.

In this design, the two groove structures 5 can better disperse the stress, reduce the risk of crack on the array substrate, and improve the manufacturing reliability and the product yield.

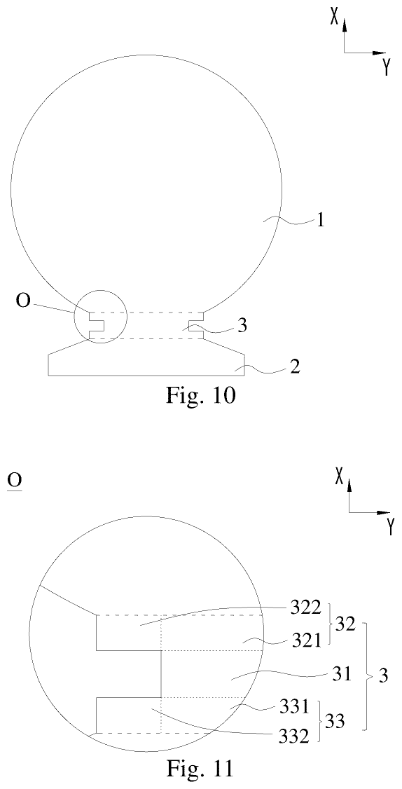

In some embodiments, referring to FIG. 10 and FIG. 11, the maximum width of the bending part 3 in the second direction Y is not larger than a minimum width of the second body 2 in the second direction Y, the bending part 3 further includes a second connecting part 33 arranged on a side of the bending body 31 near the second body 2, the second connecting part 33 includes a second connecting segment 331 and at least one second external expansion segment 332 located on at least one side of the second connecting segment 331 in the second direction Y, the bending body 31 is connected to the second body 2 through the second connecting segment 331, and in the first direction X, two ends of the bending body 31 in the second direction Y are flush with two ends of the second connecting segment 331 in the second direction Y, respectively.

The maximum width of the bending part 3 in the second direction Y is not larger than the minimum width of the second body 2 in the second direction Y. The embodiments of the present application do not limit the contour and shape of the second body 2. Exemplarily, in a direction where the second body 2 is away from the bending region, the width of the second body 2 in the second direction Y gradually increases firstly, and then remains unchanged. In this case, optionally, at least a portion of the second electric-conducting part 21 extends along the outer contour of the second body 2, that is, the portion of the second electric-conducting part 21 used to connect the conductive part 4 is the fan-out structure, so as to increase a distance between two second electric-conducting parts 21 in the second direction.

The width of the array substrate in the second direction Y is rapidly changed not only at the connection between the bending part 3 and the first body 1, but also at the connection between the bending part 3 and the second body 2. Under the influence of uneven force on the array substrate, it is prone to the stress concentration at the connection between the bending part 3 and the second body 2.

Therefore, in the embodiments of the present application, in addition to the first external expansion segment 322, at least one second external expansion segment 332 is also provided. At least one second external expansion segment 332 is located on at least one side of the second connecting segment 331 in the second direction Y, thereby increasing the strength of an end of the second connecting segment 331 in the second direction Y. Due to the certain size of the second external expansion segment 332, the stress and strength can be dispersed at the position of the end, thereby reducing the risk of stress concentration at the position of the end. Optionally, there are two second external expansion segments 332, which are located on two sides of the second connecting segment 331 in the second direction Y, respectively.

In some embodiments, referring to FIG. 1 and FIG. 3, the first body 1 is a circular structure, a diameter of the circular structure is L1, a width of the bending body 31 in the second direction Y is L2, and L1 and L2 satisfy: 10%≤L2/L1≤30%.

The first body 1 is the circular structure and is suitable for a wearable display product, such as an electronic watch. The width L2 of the bending body 31 in the second direction Y is equivalent to a corresponding diameter of the bending part 3 at a mounting position on the first body 1. When L2/L1 is too small, it indicates that the width change of the array substrate at the connection between the bending part 3 and the first body 1 is too significant, which is not conducive to wiring arrangement. In addition, it is prone to the stress concentration during the module operation. When L2/L1 is too large, it indicates that the bending part 3 occupies too much space relative to the first body 1, which may result in too small size of the first body 1, and be not conducive to the display effect of the display panel.

Therefore, in the embodiments of the present application, L2/L1 is set between 10% and 30% to increase the displayable area of the display panel while meeting the manufacturing needs of the array substrate, thereby improving the using experience of the user. Exemplarily, L2/L1 may be 10%, 15%, 20%, 25% or 30%.

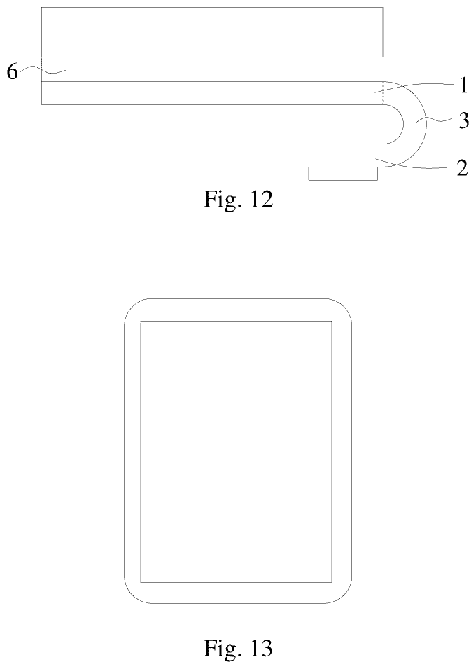

In a second aspect, referring to FIG. 12, embodiments of the present application provide a display panel including the array substrate according to any one of the aforementioned embodiments and a light-emitting member layer 6. An orthographic projection of the light-emitting member layer 6 on the array substrate is located within the first body 1.

In the display panel, the second body 2 in the array substrate needs to be bent to a side of the first body 1 in the thickness direction through the bending part 3. The light-emitting member layer 6 is located on the array substrate and includes a plurality of light-emitting units for achieving the light-emitting effect. The plurality of light-emitting units include but are not limited to red light-emitting units, green light-emitting units and blue light-emitting units. The light-emitting member layer 6 merely needs to be arranged within the display region of the display panel, thus, the orthographic projection of the light-emitting member layer 6 on the array substrate can be located within the first body 1.

It should be noted that, in addition to the light-emitting member layer and the array substrate, the display panel further includes other functional film layers. The embodiments of the present application do not limit the types and the number of other functional film layers. In addition, the display panel provided by the embodiments of the present application can have the beneficial effect of the array substrate according to any one of the aforementioned embodiments. Referring to the description of the array substrate mentioned above for details, and the embodiments of the present application will not be repeated.

In a third aspect, referring to FIG. 13, embodiments of the present application provide a display device, including the display panel according to any one of the aforementioned embodiments.

The display device provided by the embodiments of the present application can be applicable to various display devices, such as a wearable display device. The embodiments of the present application do not limit the specific application scenarios of the display device. Of course, the display device provided by the embodiments of the present application can be applicable to any other type of display device, which is not specifically limited.

Although the present application has been described with reference to the embodiments, various modifications may be made and equivalents may be substituted for parts of the embodiments without departing from the scope of the present application. In particular, as long as there is no structural conflict, the technical features mentioned in the embodiments can be combined in any manner. The present application is not limited to the specific embodiments disclosed herein, but includes all technical solutions falling within the scope of the claims.

What is claimed is:

1. An array substrate, comprising a first body, a bending part and a second body arranged in a first direction, wherein the first body is connected to the second body through the bending part, a maximum width of the bending part in a second direction is smaller than a maximum width of the first body in the second direction, and the first direction intersects with the second direction;
the bending part comprises a bending body and a first connecting part arranged on a side of the bending body near the first body, the first connecting part comprises a first connecting segment and at least one first external expansion segment located on at least one side of the first connecting segment in the second direction, the bending body is connected to the first body through the first connecting segment, and in the first direction, two ends of the bending body in the second direction are flush with two ends of the first connecting segment in the second direction, respectively.

2. The array substrate according to claim 1, wherein a first edge is arranged on a side of the at least one first external expansion segment away from the first body in the first direction, and a second edge is arranged on a side of the at least one first external expansion segment away from the first connecting segment in the second direction; and
at least one of the first edge and the second edge is provided as a curved structure.

3. The array substrate according to claim 1, wherein a first edge extending in the second direction is arranged on a side of the at least one first external expansion segment away from the first body in the first direction, and
a second edge extending in the first direction is arranged on a side of the at least one first external expansion segment away from the first connecting segment in the second direction.

4. The array substrate according to claim 3, wherein the first edge is perpendicular to or at an obtuse angle with the second edge.

5. The array substrate according to claim 3, wherein the at least one first external expansion segment further comprises an arc-shaped connecting segment connecting the first edge with the second edge.

6. The array substrate according to claim 3, wherein two of the at least one first external expansion segments are provided and located on two sides of the first connecting segment in the second direction, respectively.

7. The array substrate according to claim 1, comprising a first electric-conducting part located inside the first body, a second electric-conducting part located inside the second body and a conductive part located within the bending part connecting the first electric-conducting part with the second electric-conducting part; and
at least a portion of the conductive part is located inside the at least one first external expansion segment.

8. The array substrate according to claim 7, wherein the conductive part comprises at least one first sub-segment connected to the first electric-conducting part, at least one second sub-segment connected to the second electric-conducting part and at least one third sub-segment connected to the at least one first sub-segment and the at least one second sub-segment.

9. The array substrate according to claim 8, wherein the at least one first sub-segment extends in the first direction and at least a portion of the first sub-segment is located within the at least one first external expansion segment.

10. The array substrate according to claim 8, wherein the at least one third sub-segment extends in the second direction and at least a portion of the at least one third sub-segment is located within the at least one first external expansion segment.

11. The array substrate according to claim 8, wherein at least one of the at least one first sub-segment, second sub-segment and the at least one third sub-segment is provided as a wave-shaped wiring; or
at least one of the at least one first sub-segment, second sub-segment and the at least one third sub-segment is provided with a through hole penetrating in a thickness direction of the array substrate.

12. The array substrate according to claim 7, wherein a thickness of the conductive part is larger than a thickness of at least one of the first electric-conducting part and the second electric-conducting part.

13. The array substrate according to claim 12, wherein the thickness of the conductive part is larger than the thickness of the first electric-conducting part and the thickness of the second electric-conducting part.

14. The array substrate according to claim 13, wherein the thickness of the conductive part is H1, the thickness of the first electric-conducting part is H2, and H1 and H2 satisfy: 1000 ÅSH1−H2≤3000 Å, or the thickness of the conductive part is H1, the thickness of the second electric-conducting part is H3, and H1 and H3 satisfy: 1000 Å≤H1−H3≤3000 Å.

15. The array substrate according to claim 1, wherein connecting ends between the bending body and the at least one first external expansion segment are recessed in a direction towards the first body to form at least two groove structures, respectively, and
the at least two groove structures are symmetrically distributed on two sides of the bending part in the second direction.

16. The array substrate according to claim 1, wherein the maximum width of the bending part in the second direction is not larger than a minimum width of the second body in the second direction, the bending part further comprises a second connecting part arranged on a side of the bending body near the second body, the second connecting part comprises a second connecting segment and at least one second external expansion segment located on at least one side of the second connecting segment in the second direction, the bending body is connected to the second body through the second connecting segment, and in the first direction, two ends of the bending body in the second direction are flush with two ends of the second connecting segment in the second direction, respectively.

17. The array substrate according to claim 16, wherein two of the at least one second external expansion segments are provided and located on two sides of the second connecting segment in the second direction, respectively.

18. The array substrate according to claim 16, wherein the first body is provided as a circular structure, a diameter of the circular structure is L1, a width of the bending body in the second direction is L2, and L1 and L2 satisfy: 10%≤L2/L1≤30%.

19. A display panel, comprising:
the array substrate according to claim 1; and,
a light-emitting member layer, wherein an orthographic projection of the light-emitting member layer on the array substrate is located within the first body.

20. A display device, comprising the display panel according to claim 19.
